(19) United States
(12) Patent Application Publication
(10) Pub. No.: US 2010/0314246 A1
(43) Pub. Date: Dec. 16, 2010

(54) SPUTTER-COATING APPARATUS HAVING HEATING UNIT

(75) Inventor: HSIANG-HUNG CHEN, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/649,516

(22) Filed: Dec. 30, 2009

(30) Foreign Application Priority Data
Jun. 10, 2009 (CN) 200910303121.2

(51) Int. Cl. C23C 14/34

(52) U.S. Cl. 204/298.03

(57) ABSTRACT

A sputter-coating apparatus includes a vacuum housing, a substrate holder and a target holder positioned in the vacuum housing and facing each other, a temperature sensing unit, a heating unit, and a control unit. The substrate holder is configured for supporting a plurality of substrates to be coated and includes a central portion and a peripheral portion surrounding the central portion. The target holder is configured for mounting target material. The temperature sensing unit is configured for detecting a temperature of the central portion and a temperature of the peripheral portion. The control unit is configured for comparing the temperature of the central portion and the temperature of the peripheral portion and controlling the heating unit to heat the peripheral portion if the temperature of the central portion is greater than the temperature of the peripheral portion.

### BACKGROUND

1. Technical Field

The present disclosure relates to sputter-coating apparatuses having heating units.

2. Description of Related Art

A typical sputter-coating device includes a target holder for holding target material, a substrate holder for holding substrates to be coated, and a vacuum housing for accommodating the above elements. Energetic ions bombard the target material to vaporize the target material. The vaporized target material is then deposited on the substrates. During deposition of coats or films on the substrates, the substrates may be heated by the vaporized target material.

However, concentration of the vaporized target material in a center of the vacuum housing is typically higher than in the periphery of the vacuum housing. This results in uneven substrate temperatures on the substrate holder. The uneven temperatures may result in non-uniform coats or films deposited on the substrates.

Therefore, a sputter-coating apparatus having a heating unit is desired.

### BRIEF DESCRIPTION OF THE DRAWINGS

FIG. 1 is a sectional view of a sputter-coating apparatus, according to an exemplary embodiment.

FIG. 2 is a partial planar view of the sputter-coating apparatus of FIG. 1.

FIG. 3 is a functional blocks diagram of the sputter-coating apparatus of FIG. 1.

### DETAILED DESCRIPTION

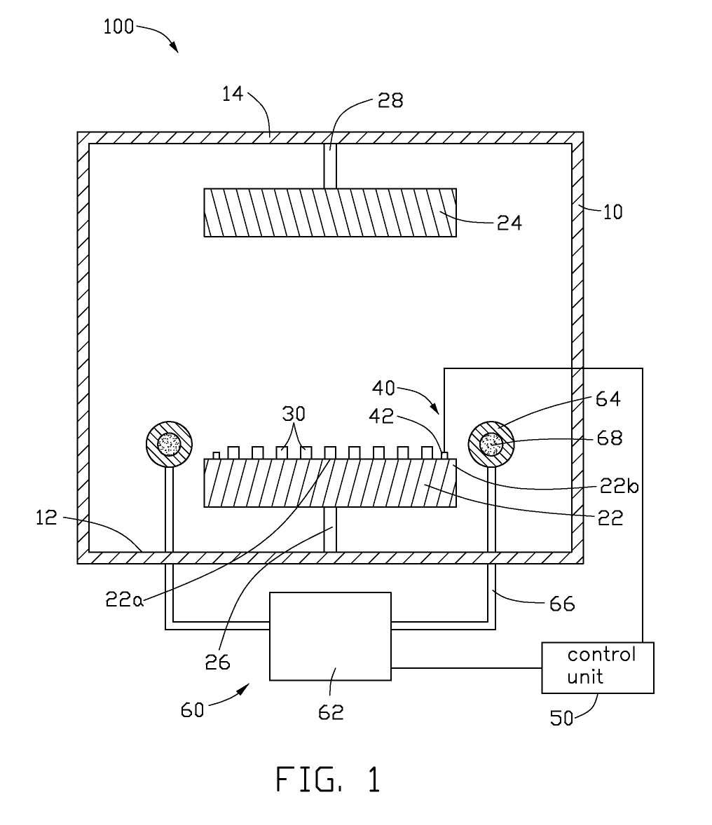

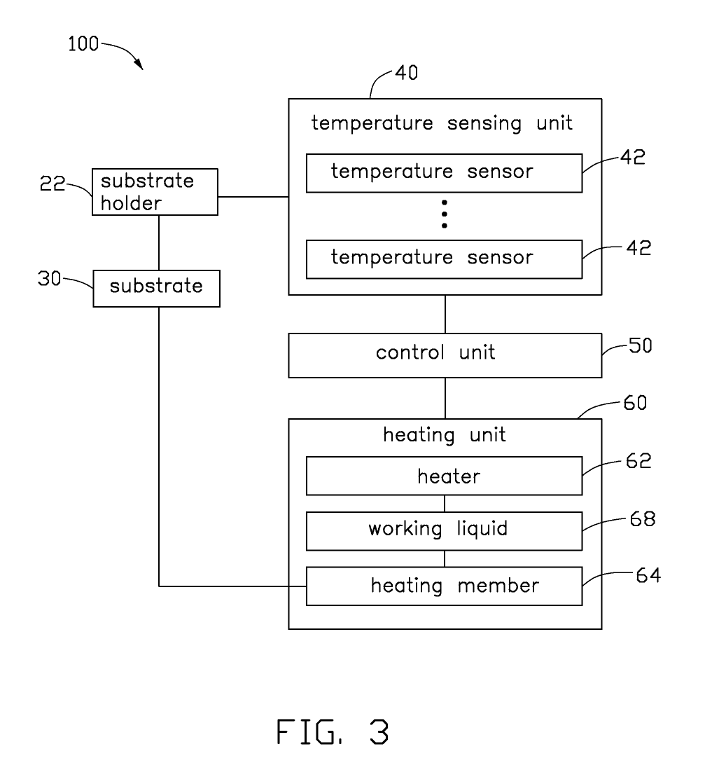

Referring to FIGS. 1 and 3, a sputter-coating apparatus 100, according to an exemplary embodiment, includes a vacuum housing 10, a substrate holder 22, a target holder 24, a temperature sensing unit 40, a control unit 50, and a heating unit 60.

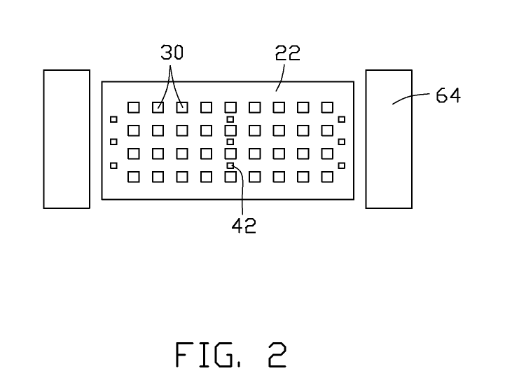

The vacuum housing 10 is airtight. The vacuum housing 10 includes a bottom wall 12 and a top wall 14 at opposite sides of the vacuum housing 10. A supporting rod 26 extends substantially perpendicular to the bottom wall 12 in the vacuum housing 10. A fixing rod 28 extends substantially perpendicular to the top wall 14 in the vacuum housing 10. The substrate holder 22 is received in the vacuum housing 10 and is supported on the bottom wall 12 by the supporting rod 26. The substrate holder 22 is configured for supporting a plurality of substrates 30 to be coated. The target holder 24 is fixedly mounted to the fixing rod 28. Therefore, the substrate holder 22 faces the target holder 24. The target holder 24 is configured for mounting target material. The plurality of substrates 30 are arrayed on the substrate holder 22 (see FIG. 2). In this embodiment, the substrate holder 22 and the target holder 24 are rectangular and the substrate holder 22 is a cathode and the target holder 24 is an anode. The substrate holder 22 includes a central portion 22a surrounded by a peripheral portion 22b.

The temperature sensing unit 40 is configured for detecting a temperature of the central portion 22a and a temperature of the peripheral portion 22b. In detail, referring to FIG. 2, the temperature sensing unit 40 includes a plurality of temperature sensors 42. The temperature sensors 42 are positioned at the central portion 22a and the peripheral portion 22b. The temperature of the central portion 22a is an average of temperatures detected by the temperature sensors 42 positioned at the central portion 22a. The temperature of the peripheral portion 22b is an average of temperatures detected by the temperature sensors 42 positioned at the peripheral portion 22b. The temperature sensor 42 may be, for example, a thermocouple temperature sensor or a thermal-resistance temperature sensor.

The control unit 50 is electrically connected to the temperature sensing unit 40 and the heating unit 60. The control unit 50 is configured for comparing the temperature of the central portion 22a with the temperature of the peripheral portion 22b and controlling the heating unit 60 to heat the peripheral portion 22b if the temperature of the central portion 22a is greater than the temperature of the peripheral portion 22b.

The heating unit 60 includes a heater 62, two heating members 64, and fours pipes 66 (only two pipes 66 are illustrated in FIG. 1). In this embodiment, the heater 62 is positioned outside the vacuum housing 10 and each heating member 64 is a heating pipe, such as a copper pipe or an aluminum pipe. The heating members 64 are filled with working liquid 68, such as water or oil. Each heating member 64 is connected to the heater 62 using the two pipes 66. Therefore, circulation of the working liquid 68 in the heating member 64 and the pipes 66 is achieved. The heater 62 may be a die heater. The two heating members 64 are positioned adjacent to two opposite sides of the peripheral portion 22b. It is to be understood that in alternative embodiments, the two heating members 64 may contact the peripheral portion 22b.

The two pipes 66 may be connected to the heating member 64 at two opposite ends of the heating member 64. The heater 62 is configured for heating and driving the working liquid 68 to the heating members 64 through the pipes 66. Therefore, when the working liquid 68 flows into the heating members 64, heat is transferred from the working liquid 68 to the heating members 64 and then is dissipated by the heating members 64.

When in use, the control unit 50 compares the temperature of the central portion 22a with the temperature of the peripheral portion 22b. If the temperature of the central portion 22a is greater than the temperature of the peripheral portion 22b, the control unit 50 controls the heating unit 60 to heat the peripheral portion 22b. In detail, the heater 62 is activated to heat and drive the working liquid 68 to the two heating members 64 through the pipes 66. Thus, the heating members 64 can heat the substrates 30 at the peripheral portion 22b of the substrate holder 22. Temperature difference between the substrates 30 at the central portion 22a and the substrates 30 at the peripheral portion 22b can be eliminated or at least alleviated. This improves uniformity of coats or films deposited on the substrates 30.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A sputter-coating apparatus, comprising:
a vacuum housing;
a substrate holder and a target holder positioned in the vacuum housing and facing each other, the substrate holder configured for supporting a plurality of substrates to be coated and comprising a central portion and a peripheral portion surrounding the central portion, the target holder configured for mounting target material;
a temperature sensing unit configured for detecting a temperature of the central portion and a temperature of the peripheral portion;
a heating unit configured for heating the peripheral portion; and
a control unit configured for comparing the temperature of the central portion with the temperature of the peripheral portion and controlling the heating unit to heat the peripheral portion if the temperature of the central portion is greater than the temperature of the peripheral portion.

2. The sputter-coating apparatus of claim 1, wherein the heating unit comprises a heater, two heating members, a plurality of pipes and working liquid, the two heating members positioned adjacent to two opposite sides of the peripheral portion, the heater positioned outside the vacuum housing and connected to the two heating members using the pipes, the heating members and the pipes filled with the working liquid, the heater configured for heating the working liquid.

3. The sputter-coating apparatus of claim 2, wherein each heating member is a copper pipe or an aluminum pipe.

4. The sputter-coating apparatus of claim 2, wherein the working liquid is water or oil.

5. The sputter-coating apparatus of claim 1, wherein the temperature sensing unit comprises a plurality of temperature sensors positioned at the central portion and the peripheral portion.

6. The sputter-coating apparatus of claim 5, wherein the temperature of the central portion is an average of temperatures detected by the temperature sensors positioned at the central portion.

7. The sputter-coating apparatus of claim 5, wherein the temperature of the peripheral portion is an average of temperatures detected by the temperature sensors positioned at the peripheral portion.

8. The sputter-coating apparatus of claim 5, wherein the temperature sensor is a thermocouple temperature sensor or a thermal-resistance temperature sensor.

9. The sputter-coating apparatus of claim 1, wherein the vacuum housing comprises a bottom wall and a top wall at opposite sides thereof, the substrate holder and the target holder positioned between the bottom wall and the top wall.

10. The sputter-coating apparatus of claim 9, wherein a supporting rod extends substantially perpendicular to the bottom wall in the vacuum housing and supports the substrate holder.

11. The sputter-coating apparatus of claim 9, wherein a fixing rod extends substantially perpendicular to the top wall in the vacuum housing and mounts the target holder.

12. The sputter-coating apparatus of claim 1, wherein the substrate holder is a cathode and the target holder is an anode.
